(19) United States
(12) Patent Application Publication
(10) Pub. No.: US 2016/0055554 A1
(43) Pub. Date: Feb. 25, 2016

(54) ELECTRONIC CATALOG

(71) Applicant: Jia-Tin-Chang Co., Ltd., New Taipei City (TW)

(72) Inventor: Yen-Tin Lee, New Taipei City (TW)

(21) Appl. No.: 14/467,934

(22) Filed: Aug. 25, 2014

(51) Int. Cl. G06Q 30/06; H05K 5/00; H05K 5/02; G06F 1/16

(52) U.S. Cl. CPC G06Q 30/0603; G06Q 30/0641; G06F 1/1626; H05K 5/0017; H05K 5/0226; H05K 5/0239

(57) ABSTRACT

An electronic catalog has a body and an exhibition apparatus. The body is an exterior protecting structure. The exhibition apparatus has a display module, a control module and an input module. The display module is mounted in the exhibition apparatus and has a screen mounted on the exhibition apparatus. The control module is electrically connected to the display module. The input module is mounted on the exhibition apparatus and is electrically connected to the control module. The input module has a storage mounted in the exhibition apparatus, and a slot disposed on the exhibition apparatus and electrically connected to the storage. Digital files are stored into the exhibition apparatus via the slot and are displayed on the screen. Thus, the old digital files can be replaced by processing files of new products rather than making new paper catalogs, thereby decreasing cost, saving resources, and facilitating convenience.

### BACKGROUND OF THE INVENTION

1. Field of the Invention

The present invention relates to a catalog of products, especially an electronic catalog that can digitally display the products.

2. Description of the Prior Arts

A conventional paper catalog of products is commonly used by dealers for advertising and selling. Products for sale, such as automobiles, motorcycles or electric appliances, are photographed and the photos are printed with some descriptions on sheets of paper, and the sheets of paper are assembled into a booklet. Consumers can see shapes and features of the products and know the contents of the products via the conventional paper catalog of products, and sellers also can introduce the contents of the products. However, the conventional paper catalog is made of printed paper. New paper catalogs have to be made when new products are released, and the previous paper catalogs can be abandoned. That would increase the usage cost for dealers and waste resources.

To overcome the shortcomings, the present invention provides an electronic catalog to mitigate or obviate the aforementioned problems.

### SUMMARY OF THE INVENTION

The main objective of the present invention is to provide an electronic catalog for decreasing the cost and saving the resources.

The electronic catalog comprises a body and an exhibition apparatus. The body is an exterior protecting structure that can be turned. The exhibition apparatus is mounted in the body and has a display module, a control module and an input module. The display module is mounted in the exhibition apparatus and has a display control unit and a screen electrically connected to the display control unit. The screen is mounted on a top surface of the exhibition apparatus. The control module is mounted on the exhibition apparatus and is electrically connected to the display module. The control module has a command unit electrically connected to the display control unit. The input module is mounted on the exhibition apparatus and is electrically connected to the control module. The input module has a storage and a slot. The storage is mounted in the exhibition apparatus and is electrically connected to the command unit. The slot is disposed on the exhibition apparatus and is electrically connected to the storage.

Other objectives, advantages and novel features of the invention will become more apparent from the following detailed description when taken in conjunction with the accompanying drawings.

### BRIEF DESCRIPTION OF THE DRAWINGS

FIG. 1 is a perspective view of an electronic catalog in accordance with the present invention;

FIG. 2 is an operational perspective view of the electronic catalog in FIG. 1; and

FIG. 3 is a circuit diagram of the electronic catalog in FIG. 1.

### DETAILED DESCRIPTION OF THE PREFERRED EMBODIMENTS

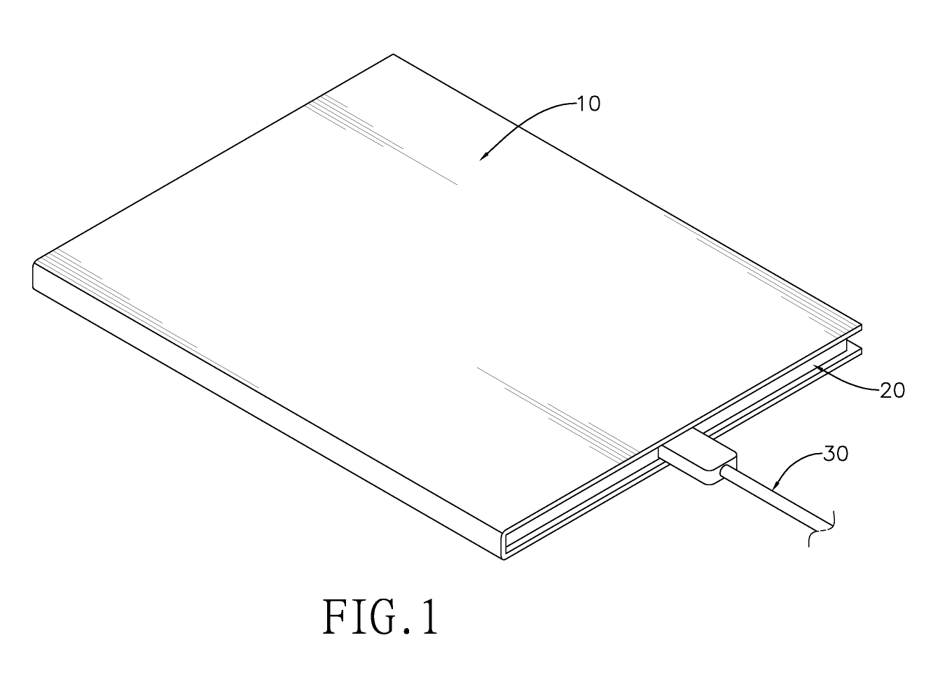

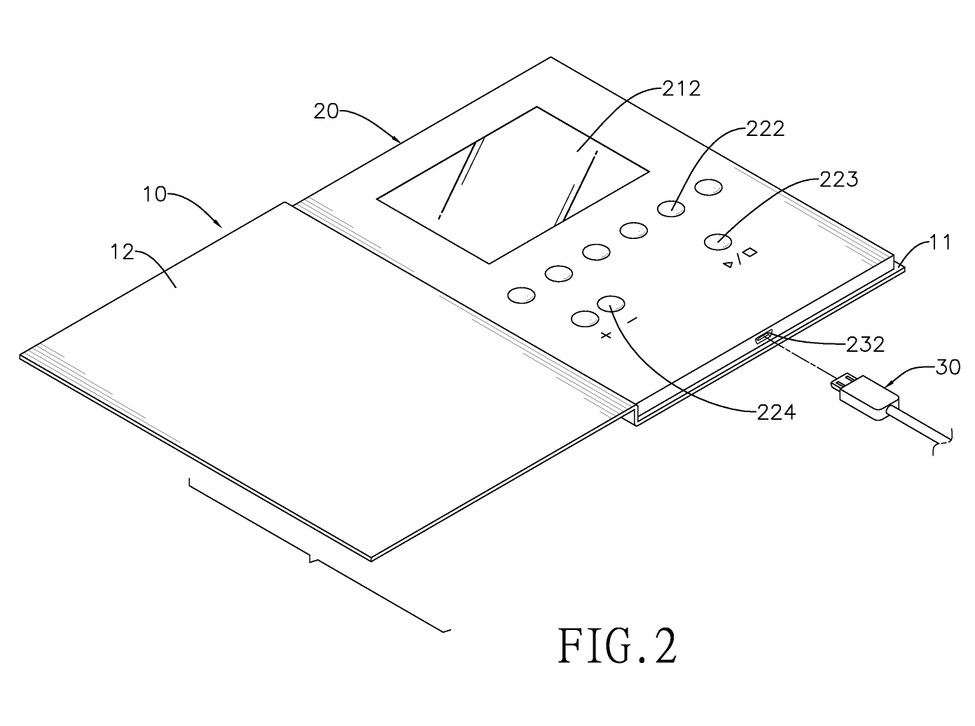

With reference to FIGS. 1 and 2, an electronic catalog in accordance with the present invention comprises a body 10 and an exhibition apparatus 20.

The body 10 is an exterior protecting structure and has a back cover 11 and a front cover 12. The back cover 11 is a rectangular plate and has an inner surface. The front cover 12 is a plate, is formed with the back cover 11, and faces the inner surface of the back cover 11. The front cover 12 has a shape corresponding to a shape of the back cover 11. The front cover 12 has a side edge connected to the back cover 11 to enable the front cover 12 to rotate relative to the back cover 11. Preferably, the body 10 is made of hardboard or plastic.

With reference to FIGS. 1 to 3, the exhibition apparatus 20 is mounted in the body 10 and has a bottom surface, a display module 21, a control module 22 and an input module 23. The bottom surface of the exhibition apparatus 20 is securely mounted on the inner surface of the back cover 11 to enable the front cover 12 to cover the exhibition apparatus 20.

The display module 21 is mounted in the exhibition apparatus 20 and has a display control unit 211 and a screen 212. The display control unit 211 is mounted in the exhibition apparatus 20. The screen 212 is mounted in the exhibition apparatus 20, is mounted on an upper half of the exhibition apparatus 20, and faces the front cover 12 of the body 10. In addition, the screen 212 is electrically connected to the display control unit 211.

The control module 22 is mounted on the exhibition apparatus 20, is electrically connected to the display module 21, and has a command unit 221, multiple category buttons 222, a play/pause button 223 and two volume buttons 224. The command unit 221 is mounted in the exhibition apparatus 20 and is electrically connected to the display control unit 211. The category buttons 222 are mounted on a front surface of the exhibition apparatus 20 at intervals, align with each other adjacent to the screen 212, and are electrically connected to the command unit 221. In a preferred embodiment of the category buttons 222, each category button 222 can be set as a listing of product models or a full introduction of various portions of a product. The play/pause button 223 is mounted on the front surface of the exhibition apparatus 20 adjacent to the category buttons 222 and is opposite to the screen 212. The volume buttons 224 are mounted on the front surface of the exhibition apparatus 20 at an interval adjacent to the category buttons 222, are opposite to the screen 212, and are electrically connected to the command unit 221.

The input module 23 is mounted on the exhibition apparatus 20 and is electrically connected to the control module 22. The input module 23 has a storage 231, a slot 232 and a cell 233. The storage 231 is mounted in the exhibition apparatus 20 and is electrically connected to the command unit 221. The slot 232 is disposed on an outer wall of the exhibition apparatus 20 and is electrically connected to the storage 231. The cell 233 is mounted in the exhibition apparatus 20 and is electrically connected to the storage 231 and the slot 232.

With reference to FIGS. 1 to 3, the electronic catalog of the present invention further has a transfer cable 30 detachably connected to the slot 232 of the input module 23. In use, digital files of products are transferred and stored in the storage of the input module 23 via the transfer cable 30, or the cell 23 is charged by an electrical outlet via the transfer cable 30 and the slot 232.

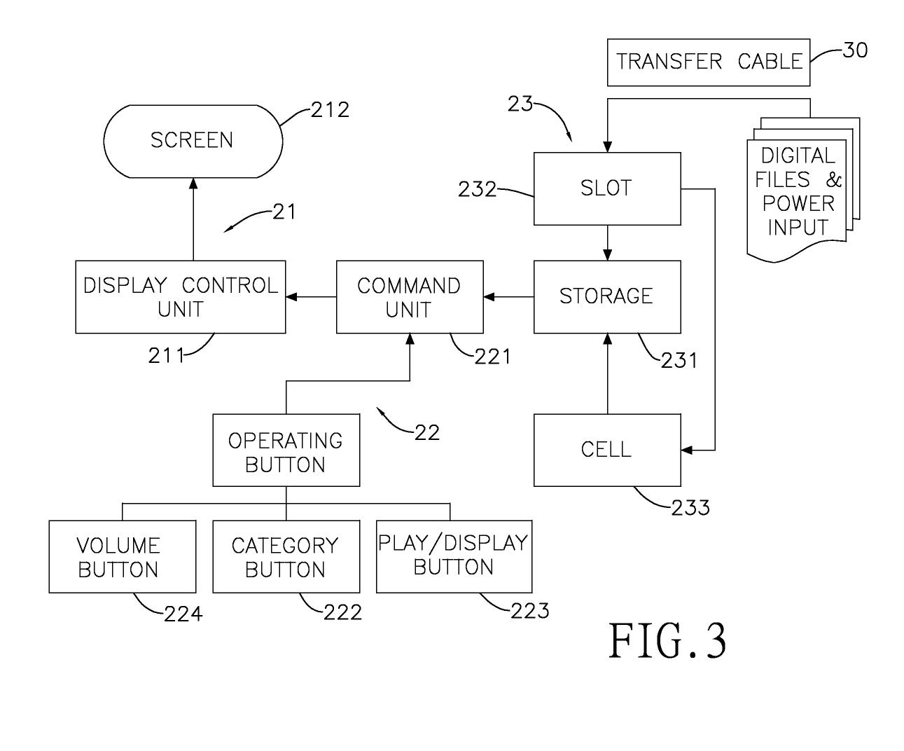

The advantage of the present invention is that the electronic catalog can be used to replace the printed paper of the conventional catalog of products by the exhibition apparatus 20 that can process transferring of digital files and can be charged. With reference to FIGS. 2 and 3, in use, users press one of the category buttons 222 to select one of the portions of the product and then press the play/pause button 223, and a corresponding digital file of the selected product is shown on the screen 212. After viewing the corresponding digital file of product, users can press other category buttons 222 or press the play/pause button 223 again to stop the display of the corresponding digital file of the product in the exhibition apparatus 20. When pressing any one of the buttons 222, 223, 224, a corresponding external instruction is inputted into the control module 22 and is decoded by the command unit 221 to be transformed into a digital signal. The digital signal is used to control the storage 231 and the screen 212. Furthermore, as old digital files of products become useless when new products are released, the old digital files can be replaced by storing the digital files of new products into the storage 231 via the transfer cable 30 and the slot 231. Therefore, the electronic catalog of the present invention can be used repeatedly, and has advantages of convenience, decreasing costs and saving the resources compared to the conventional printed catalog of products.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. An electronic catalog comprising:
a body being an exterior protecting structure; and
an exhibition apparatus mounted in the body and having
a display module mounted in the exhibition apparatus and having
a display control unit mounted in the exhibition apparatus; and
a screen electrically connected to the display control unit and mounted on a top surface of the exhibition apparatus;
a control module mounted on the exhibition apparatus, electrically connected to the display module, and having
a command unit mounted in the exhibition apparatus and electrically connected to the display control unit; and
an input module mounted on the exhibition apparatus, electrically connected to the control module, and having
a storage mounted in the exhibition apparatus and electrically connected to the command unit; and
a slot disposed on the exhibition apparatus and electrically connected to the storage.

2. The electronic catalog as claimed in claim 1, wherein
the body has
a back cover being a rectangular plate and having an inner surface; and
a front cover formed with the back cover, facing the inner surface of the back cover, and having a shape corresponding to a shape of the back cover and a side edge connected to the back cover.

3. The electronic catalog as claimed in claim 1, wherein the body is made of hardboard or plastic.

4. The electronic catalog as claimed in claim 2, wherein the body is made of hardboard or plastic.

5. The electronic catalog as claimed in claim 2, wherein the screen is mounted on an upper half of the exhibition apparatus and faces the front cover of the body.

6. The electronic catalog as claimed in claim 5, wherein the control module has
multiple category buttons mounted on a front surface of the exhibition apparatus at intervals, aligning with each other adjacent to the screen, and electrically connected to the command unit;
a play/pause button mounted on the front surface of the exhibition apparatus adjacent to the category buttons and being opposite to the screen; and
two volume buttons mounted on the front surface of the exhibition apparatus at an interval adjacent to the category buttons and being opposite to the screen;
wherein the category buttons, the play/pause button, and the volume buttons are electrically connected to the command unit.

7. The electronic catalog as claimed in claim 6, wherein the slot is disposed on an outer wall of the exhibition apparatus.

8. The electronic catalog as claimed in claim 7, wherein the electronic catalog has a transfer cable detachably connected to the slot of the input module.

9. The electronic catalog as claimed in claim 8, wherein the input module has a cell mounted in the exhibition apparatus and electrically connected to the storage and the slot.
